(19) United States
(12) Patent Application Publication
(10) Pub. No.: US 2024/0384907 A1
(43) Pub. Date: Nov. 21, 2024

(54) VAPOR CYCLE SYSTEM FOR COOLING COMPONENTS AND ASSOCIATED METHOD

(71) Applicant: General Electric Company, Schenectady, NY (US)

(72) Inventor: Kevin Edward Hinderliter, Cincinnati, OH (US)

(21) Appl. No.: 18/788,644

(22) Filed: Jul. 30, 2024

Related U.S. Application Data
(62) Division of application No. 17/078,642, filed on Oct. 23, 2020.

(51) Int. Cl. F25B 49/02; F25B 5/02; F25B 6/04; F25B 40/02

(52) U.S. Cl. CPC F25B 49/02; F25B 5/02; F25B 6/04; F25B 40/02; F25B 2313/0311; F25B 2313/0314

(57) ABSTRACT

A vapor cycle system for cooling components includes a refrigeration circuit through which a mass of a refrigerant flows. The refrigeration circuit, in turn, includes a compressor, a first condenser, a second condenser fluidly coupled to the first condenser in series, an expansion valve, and an evaporator. Furthermore, the system includes a refrigerant charge control device configured to increase or decrease the mass of the refrigerant flowing through the refrigeration circuit, wherein the refrigerant charge control device comprises a storage device.

### CROSS-REFERENCE TO RELATED APPLICATIONS

This application is a divisional application of U.S. application Ser. No. 17/078,642 filed Oct. 23, 2020, which is hereby incorporated by reference in its entirety.

### FIELD

The present disclosure generally pertains to systems and methods for cooling components and, more particularly, to a vapor cycle system having series condensers for cooling components, such as one or more aircraft components, and an associated method.

### BACKGROUND

In recent years, the number and complexity of the electronic devices present within an aircraft has grown dramatically. As such, the power consumption of and, thus, the heat generated by such electronic devices has also increased significantly. In this respect, air cooling systems are typically unable to provide sufficient cooling to the electronic devices of the aircraft. Thus, vapor cycle systems have been used in many aircraft to meet the increased cooling requirements of aircraft's electronic devices.

In general, it is advantageous for vapor cycle systems to reject heat to multiple heat sinks simultaneously or independently. For example, such heat sinks may be the fuel supplied to the aircraft's engines, ram air, and/or air within an bypass duct of the aircraft's engines. However, during operation of the aircraft, the availability of the heat sinks may vary through different regions of the flight envelope or mission. That is, when one heat sink is available, another heat sink is may be unavailable. As such, the mass of refrigerant present within the system may have differing effects on the operation of the vapor cycle system depending on which condenser(s) is being used to reject heat from the electronic devices.

Accordingly, an improved vapor cycle system for cooling components, such as aircraft components, and an associated method would be welcomed in the technology.

### BRIEF DESCRIPTION

Aspects and advantages of the invention will be set forth in part in the following description, or may be obvious from the description, or may be learned through practice of the invention.

In one aspect, the present subject matter is directed to a vapor cycle system for cooling components. The system includes a refrigeration circuit through which a mass of a refrigerant flows. The refrigeration circuit, in turn, includes a compressor, a first condenser, a second condenser fluidly coupled to the first condenser in series, an expansion valve, and an evaporator. Furthermore, the system includes a refrigerant charge control device configured to increase or decrease the mass of the refrigerant flowing through the refrigeration circuit.

In another aspect, the present subject matter is directed to a method for cooling components using a vapor cycle system. The vapor cycle system includes a refrigeration circuit through which a mass of a refrigerant flows. The refrigeration circuit, in turn, includes a first condenser and a second condenser fluidly coupled to the first condenser in series. Additionally, the vapor cycle system includes a refrigerant charge control device configured to increase or decrease the mass of the refrigerant flowing through the refrigeration circuit. As such, the method includes monitoring, with a computing system, a pressure of the refrigerant exiting the second condenser. Furthermore, the method includes monitoring, with the computing system, a temperature of the refrigerant exiting the second condenser. Moreover, the method includes controlling, with the computing system, an operation of the refrigerant charge control device to adjust the mass of the refrigerant flowing through the refrigeration circuit based on the monitored pressure and the monitored temperature.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 is a side view of one embodiment of an aircraft;

FIG. 2 is a schematic cross-sectional view of one embodiment of a gas turbine engine of an aircraft;

FIG. 3 is a schematic view of one embodiment of a vapor cycle system for cooling components;

FIG. 4 is a schematic view of another embodiment of a vapor cycle system for cooling components;

FIG. 5 is a schematic view of a further embodiment of a vapor cycle system for cooling components;

FIG. 6 is a schematic view of another embodiment of a vapor cycle system for cooling components;

FIG. 7 is a schematic view of a further embodiment of a vapor cycle system for cooling components;

FIG. 8 is a schematic view of yet another embodiment of a vapor cycle system for cooling components;

FIG. 9 is a schematic view of yet a further embodiment of a vapor cycle system for cooling components;

FIG. 10 is a schematic view of another embodiment of a vapor cycle system for cooling components; and

FIG. 11 is a flow diagram of one embodiment of a method for cooling components using a vapor cycle system.

Repeat use of reference characters in the present specification and drawings is intended to represent the same or analogous features or elements of the present invention.

### DETAILED DESCRIPTION

Reference now will be made in detail to exemplary embodiments of the presently disclosed subject matter, one or more examples of which are illustrated in the drawings. Each example is provided by way of explanation and should not be interpreted as limiting the present disclosure. In fact, it will be apparent to those skilled in the art that various modifications and variations can be made in the present disclosure without departing from the scope or spirit of the present disclosure. For instance, features illustrated or described as part of one embodiment can be used with another embodiment to yield a still further embodiment. Thus, it is intended that the present disclosure covers such modifications and variations as come within the scope of the appended claims and their equivalents.

As used herein, the terms “first”, “second”, and “third” may be used interchangeably to distinguish one component from another and are not intended to signify location or importance of the individual components.

Furthermore, the terms “upstream” and “downstream” refer to the relative direction with respect to fluid flow in a fluid pathway. For example, “upstream” refers to the direction from which the fluid flows, and “downstream” refers to the direction to which the fluid flows.

Additionally, the terms “low,” “high,” or their respective comparative degrees (e.g., lower, higher, where applicable) each refer to relative speeds within an engine, unless otherwise specified. For example, a “low-pressure turbine” operates at a pressure generally lower than a “high-pressure turbine.” Alternatively, unless otherwise specified, the aforementioned terms may be understood in their superlative degree. For example, a “low-pressure turbine” may refer to the lowest maximum pressure turbine within a turbine section, and a “high-pressure turbine” may refer to the highest maximum pressure turbine within the turbine section.

In general, the present subject matter is directed to a vapor cycle system for cooling components and an associated method. As will be described below, in some embodiments, the disclosed vapor cycle system may be used to cool one or more components or systems (e.g., one or more electronic devices) of an aircraft. In several embodiments, the vapor cycle system includes a compressor, a first condenser, a second condenser fluidly coupled to the first condenser in series, an expansion valve, and an evaporator. The term condenser is generically used to describe any heat exchanger facilitating heat transfer from the refrigerant to a thermal sink. These heat exchangers may be described and/or function as de-superheaters or subcoolers in addition to condensers. As such, a mass of a refrigerant flows through the vapor cycle system to transfer heat from low-temperature heat sources (e.g., one or more electronic devices of an aircraft, cabin heat, environmental control systems, etc.) to a higher temperature thermal sink (e.g., fuel being supplied to the aircraft, anti-ice surfaces, engine bypass ducts, ram air, etc.). Specifically, during operation, the refrigerant absorbs heat from the component(s) while flowing through the evaporator and rejects this heat to the fluid while flowing through the condensers.

Additionally, the vapor cycle system includes a refrigerant charge control device configured to increase or decrease the mass of the refrigerant flowing through the refrigeration circuit. Specifically, when the pressure of the refrigerant exiting the second condenser exceeds a maximum pressure value, the refrigerant charge control device may decrease the mass of the refrigerant flowing through the refrigeration circuit. Moreover, when a determined subcool value of the refrigerant exiting the second condenser falls below a minimum subcool value, the refrigerant charge control device may increase the mass of the refrigerant flowing through the refrigeration circuit. For example, in several embodiments, the refrigerant charge control device may include a first control valve, a tank, and a second control valve in parallel with the refrigeration circuit. In such embodiments, to decrease the mass of the refrigerant within the refrigeration circuit, the first valve is opened to allow a portion of the refrigerant to flow from the refrigeration circuit into the tank. Conversely, in such embodiments, the second valve is opened to allow refrigerant to flow from the tank into the refrigeration circuit, thereby increasing the mass of the refrigerant within the refrigeration circuit. In other embodiments, the refrigerant charge control device includes a cylinder or other storage device that allows refrigerant to be added or removed from the refrigeration circuit.

The refrigerant charge control device provides one or more technical advantages. More specifically, the disclosed vapor cycle system includes first and second condensers in series. In general, one condenser may reject heat from the refrigeration circuit in certain instances, while the other condenser may reject heat from the refrigeration circuit in other instances. However, the mass of refrigerant necessary for proper operation of the refrigeration circuit may vary depending on which condenser is being used to reject heat from the refrigerant. As such, the refrigerant charge control device increases and decreases the mass of the refrigerant within the refrigeration circuit (e.g., based on the temperature and/or the pressure of the refrigerant exiting the second condenser) to maintain proper operation of the vapor cycle system.

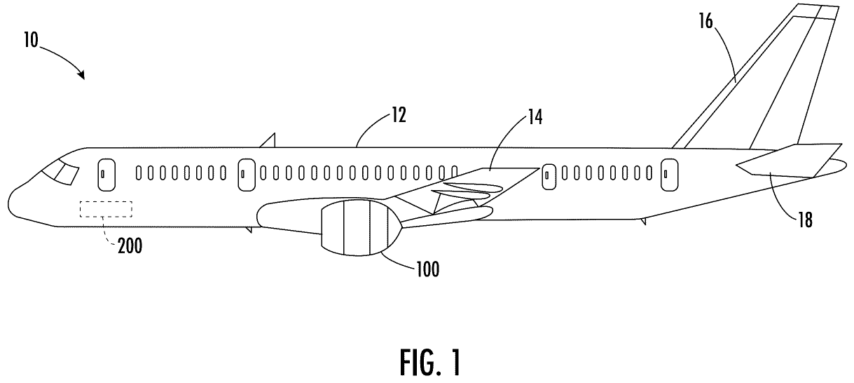

Referring now to the drawings, FIG. 1 is a side view of one embodiment of an aircraft 10. As shown, in several embodiments, the aircraft 10 includes a fuselage 12 and a pair of wings 14 (one is shown) extending outward from the fuselage 12. In the illustrated embodiment, a gas turbine engine 100 is supported on each wing 14 to propel the aircraft through the air during flight. Additionally, as shown, the aircraft 10 includes a vertical stabilizer 16 and a pair of horizontal stabilizers 18 (one is shown). However, in alternative embodiments, the aircraft 10 may include any other suitable configuration, such as any other suitable number or type of engines.

Furthermore, the aircraft 10 may include a vapor cycle system 200 for cooling one or more components of the aircraft 10. Specifically, in several embodiments, the vapor cycle system 200 is configured to cool one or more electronic devices of the aircraft, such as one or more navigation devices, communications devices, engine controllers, and/or the like. In such embodiments, the vapor cycle system 200 is configured to transfer heat from the electronic device(s) of the aircraft 10 to one or more fluids that support the operation of the aircraft 10. Such fluid(s) act as heat sinks and may include the fuel supplied to the engines 100, ram air, air flowing through an engine bypass duct of the aircraft 10, and/or the air used to pressurize a cabin of the aircraft 10. However, in alternative embodiment, the vapor cycle system 200 may be configured to transfer heat between any other component(s) of the aircraft 10 and any other suitable fluid(s).

The configuration of the aircraft 10 described above and shown in FIG. 1 is provided only to place the present subject matter in an exemplary field of use. Thus, the present subject matter may be readily adaptable to any manner of aircraft.

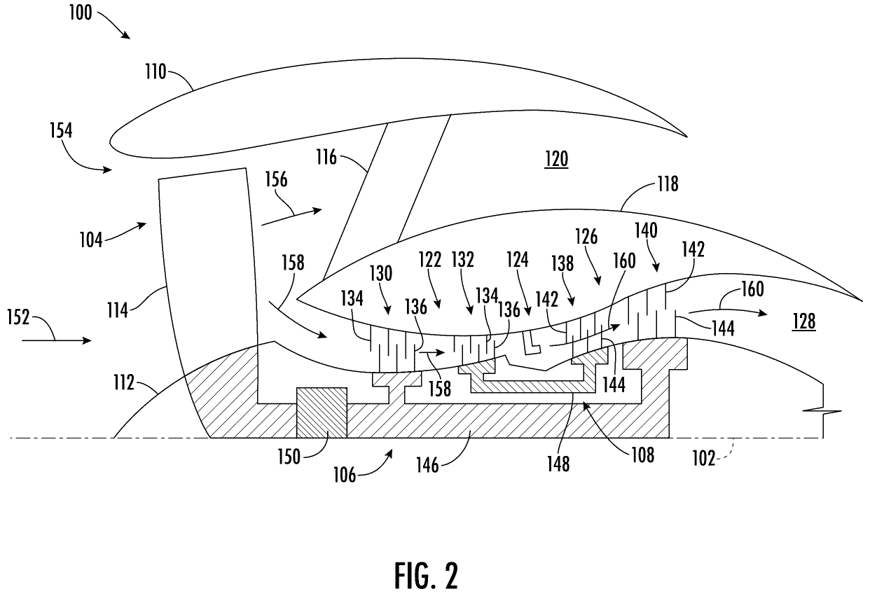

FIG. 2 is a schematic cross-sectional view of one embodiment of a gas turbine engine 100. In the illustrated embodiment, the engine 100 is configured as a high-bypass turbofan engine. However, in alternative embodiments, the engine 100 may be configured as a propfan engine, a turbojet engine, a turboprop engine, a turboshaft gas turbine engine, or any other suitable type of gas turbine engine.

In general, the engine 100 extends along an axial centerline 102 and includes a fan 104, a low-pressure (LP) spool 106, and a high pressure (HP) spool 108 at least partially encased by an annular nacelle 110. More specifically, the fan 104 may include a fan rotor 112 and a plurality of fan blades 114 (one is shown) coupled to the fan rotor 112. In this respect, the fan blades 114 are circumferentially spaced apart and extend radially outward from the fan rotor 112. Moreover, the LP and HP spools 106, 108 are positioned downstream from the fan 104 along the axial centerline 102. As shown, the LP spool 106 is rotatably coupled to the fan rotor 112, thereby permitting the LP spool 106 to rotate the fan 114. Additionally, a plurality of outlet guide vanes or struts 116 circumferentially spaced apart from each other and extend radially between an outer casing 118 surrounding the LP and HP spools 106, 108 and the nacelle 110. As such, the struts 116 support the nacelle 110 relative to the outer casing 118 such that the outer casing 118 and the nacelle 110 define a bypass airflow passage 120 positioned therebetween.

The outer casing 118 generally surrounds or encases, in serial flow order, a compressor section 122, a combustion section 124, a turbine section 126, and an exhaust section 128. For example, in some embodiments, the compressor section 122 may include a low-pressure (LP) compressor 130 of the LP spool 106 and a high-pressure (HP) compressor 132 of the HP spool 108 positioned downstream from the LP compressor 130 along the axial centerline 102. Each compressor 130, 132 may, in turn, include one or more rows of stator vanes 134 interdigitated with one or more rows of compressor rotor blades 136. Moreover, in some embodiments, the turbine section 126 includes a high-pressure (HP) turbine 138 of the HP spool 108 and a low-pressure (LP) turbine 140 of the LP spool 106 positioned downstream from the HP turbine 138 along the axial centerline 102. Each turbine 138, 140 may, in turn, include one or more rows of stator vanes 142 interdigitated with one or more rows of turbine rotor blades 144.

Additionally, the LP spool 106 includes the low-pressure (LP) shaft 146 and the HP spool 108 includes a high pressure (HP) shaft 148 positioned concentrically around the LP shaft 146. In such embodiments, the HP shaft 148 rotatably couples the rotor blades 144 of the HP turbine 138 and the rotor blades 136 of the HP compressor 132 such that rotation of the HP turbine rotor blades 144 rotatably drives HP compressor rotor blades 136. As shown, the LP shaft 146 is directly coupled to the rotor blades 144 of the LP turbine 140 and the rotor blades 136 of the LP compressor 130. Furthermore, the LP shaft 146 is coupled to the fan 104 via a gearbox 150. In this respect, the rotation of the LP turbine rotor blades 144 rotatably drives the LP compressor rotor blades 136 and the fan blades 114.

In several embodiments, the engine 100 may generate thrust to propel an aircraft. More specifically, during operation, air (indicated by arrow 152) enters an inlet portion 154 of the engine 100. The fan 104 supplies a first portion (indicated by arrow 156) of the air 152 to the bypass airflow passage 120 and a second portion (indicated by arrow 158) of the air 152 to the compressor section 122. The second portion 158 of the air 152 first flows through the LP compressor 130 in which the rotor blades 136 therein progressively compress the second portion 158 of the air 152. Next, the second portion 158 of the air 152 flows through the HP compressor 132 in which the rotor blades 136 therein continue progressively compressing the second portion 158 of the air 152. The compressed second portion 158 of the air 152 is subsequently delivered to the combustion section 124. In the combustion section 124, the second portion 158 of the air 152 mixes with fuel and burns to generate high-temperature and high-pressure combustion gases 160. Thereafter, the combustion gases 160 flow through the HP turbine 138 which the HP turbine rotor blades 144 extract a first portion of kinetic and/or thermal energy therefrom. This energy extraction rotates the HP shaft 148, thereby driving the HP compressor 132. The combustion gases 160 then flow through the LP turbine 140 in which the LP turbine rotor blades 144 extract a second portion of kinetic and/or thermal energy therefrom. This energy extraction rotates the LP shaft 146, thereby driving the LP compressor 130 and the fan 104 via the gearbox 150. The combustion gases 160 then exit the engine 100 through the exhaust section 128.

The configuration of the gas turbine engine 100 described above and shown in FIG. 2 is provided only to place the present subject matter in an exemplary field of use. Thus, the present subject matter may be readily adaptable to any manner of gas turbine engine configuration, including other types of aviation-based gas turbine engines, marine-based gas turbine engines, and/or land-based/industrial gas turbine engines.

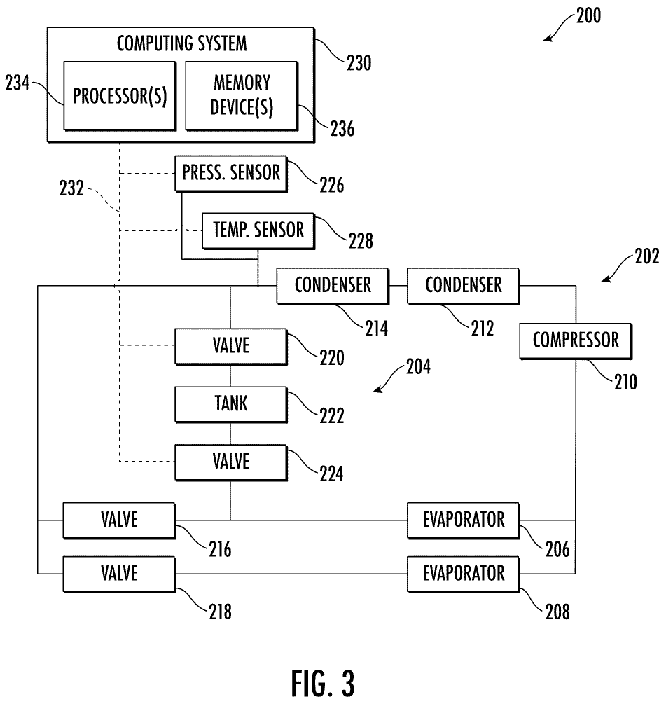

FIG. 3 is a schematic view of one embodiment of a vapor cycle system 200 for cooling components. In general, the vapor cycle system 200 includes a refrigeration circuit 202 and a refrigerant charge control device 204. More specifically, a mass of a refrigerant flows through the refrigeration circuit 202 to transfer heat from one or more components to one or more fluids, thereby cooling such component(s). As will be described below, the refrigerant charge control device 204 adjusts the mass the refrigerant within the refrigeration circuit 202 to maintain proper operation of the vapor cycle system 200.

The vapor cycle system 200 may be used to transfer heat from any suitable component(s) to any suitable fluid(s). For example, in several embodiments, the vapor cycle system 200 may be configured to transfer heat from one or more components of the aircraft 10 (e.g., one or more electronic device(s)) to one or more fluids supporting the operation of the aircraft 10 (e.g., the fuel supplied to the engines 100 and/or ram air). However, in alternative embodiments, the vapor cycle system 200 may be configured to transfer heat from any other suitable component(s) of the aircraft 10 to any suitable fluid(s) supporting the operation of the aircraft 10. Moreover, in further embodiments, the vapor cycle system 200 may be configured to transfer heat from any suitable non-aircraft/aviation component(s) to any suitable non-aircraft/aviation fluid(s).

The refrigeration circuit 202 may include any suitable components configured to absorb heat and subsequently reject this heat. In several embodiments, the refrigeration circuit 202 includes one or more evaporators 206, 208; a compressor 210; a plurality of condensers 212, 214; and one or more expansion valves 216, 218. Specifically, as shown, in the illustrated embodiment, the refrigeration circuit 202 includes first and second evaporators 206, 208 in parallel with each other and a compressor 210 fluidly coupled to and in series with the evaporators 206, 208 Furthermore, in the illustrated embodiment, the refrigeration circuit 202 includes a first condenser 212 fluidly coupled to and in series with the compressor 210 and a second condenser 214 fluidly coupled to and in series with the first condenser 212. Additionally, in the illustrated embodiment, the refrigeration circuit 202 includes first and second expansion valves 216, 218 in parallel with each other and in series with the second condenser 214. Moreover, the refrigeration circuit 202 includes suitable tubing, hoses, piping, or other conduits to fluidly couple the above-described components of the circuit 202. However, in alternative embodiments, the refrigeration circuit 202 may have any other suitable configuration. For example, the refrigeration circuit 202 may include three or more condensers in series with each other. In addition, the refrigeration circuit 202 may include one or three or more evaporators and one or three or more expansion valves.

In operation, a mass of a refrigerant flows through the refrigeration circuit 202 to transfer heat from one or more components to one or more fluids, thereby cooling such component(s). More specifically, in the illustrated embodiment, the refrigerant absorbs heat from the component(s) while flowing through the evaporators 206, 208. Such heat absorption causes the refrigerant to evaporate. The compressor 210 then pressurizes the gaseous refrigerant and supplies the pressurized gaseous refrigerant to the condensers 212, 214. The condensers 212, 214, in turn, transfer the heat absorbed by the refrigerant in the evaporators 206, 208 to the fluid(s), thereby rejecting heat from the refrigeration circuit 202. Such heat rejection liquifies the refrigerant. Thereafter, the refrigerant flows through the expansion valves 216, 218, which decreases the pressure of the refrigerant and facilitates vaporization of the refrigerant when heat is absorbed through the evaporators 206, 208. The vaporized refrigerant (i.e., a liquid-gaseous mixture of the refrigerant) then flows to the evaporators 206, 208.

The first condenser 212 may reject heat from the refrigeration circuit 202 in certain instances, while the second condenser 214 may reject heat from the refrigeration circuit 202 in other instances. More specifically, in several embodiments, the first condenser 212 may be configured to transfer heat from the refrigerant to the fuel supplied to the engine(s) 100 of the aircraft 10. Moreover, in such embodiments, the second condenser 214 may be configured to transfer heat from the refrigerant to the air in an engine bypass duct. For example, when the engine(s) 100 of the aircraft 10 is operating under a high load (e.g., when traveling at supersonic speeds), the fan bypass duct air may be too hot for heat to be transferred from the refrigerant thereto. However, the large volume of fuel is being supplied the engine(s) 100 in such instances allows the first condenser 212 to provide heat rejection. Conversely, when the aircraft 10 is cruising at high altitudes and lower speeds, the volume of fuel being supplied to the engine(s) 100 may be too small to provide heat rejection. However, in such instances, the fan bypass duct air temperature may allow the second condensers 214 to provide heat rejection. However, in alternative embodiments, the first and second condensers 212, 214 may be configured to transfer heat from the refrigerant to any other suitable fluids or heat sinks and may operate simultaneously.

Any suitable refrigerant may flow through the refrigeration circuit 202 to support its operation. For example, in some embodiments, the refrigerant may be 1,1,1,2-Tetrafluoroethane, typically known as R-134a.

As mentioned above, the vapor cycle system 200 includes the refrigerant charge control device 204 to adjust the mass of the refrigerant flowing through the refrigeration circuit 202. More specifically, the mass of refrigerant that supports proper operation of the refrigeration circuit 200 may vary depending on which condenser 212, 214 is being used to reject heat from the refrigeration circuit 200. As will be described below, the temperature and/or pressure of the refrigerant after exiting the second condenser 214 (or the last condenser through which the refrigerant flows before reaching the expansion valves 216, 218) is dependent on which condenser 212, 214 is being used to reject heat from the refrigeration circuit 202. In this respect, based on the temperature and/or pressure of the refrigerant after exiting the second condenser 214, the refrigerant charge control device 204 may add or remove refrigerant from the refrigeration circuit 202.

As shown, in several embodiments, the refrigerant charge control device 204 includes a first control valve 220, a tank 222, and a second control valve 224. More specifically, in such embodiments, the refrigerant charge control device 204 is fluidly coupled to the refrigeration circuit 202 such that the refrigerant charge control device 204 is in parallel with the first expansion valve 216. In this respect, the first control valve 220 is fluidly coupled to the refrigeration circuit 202 at a location between an outlet (not shown) of the second condenser 214 and the expansion valves 216, 218. Furthermore, the tank 222 is fluidly coupled to and in series with the first control valve 220. Moreover, the second control valve 224 is fluidly coupled to and in series with the tank 222. As such, to reduce the mass of the refrigerant within the refrigeration circuit 202, the first control valve 220 is opened and the second control valve 224 is closed. The second control valve 224 may be placed in a weeping position to better facilitate the migration of the refrigerant into the tank 222. In such instances, a portion of the refrigerant flows from the refrigeration circuit 202 through the first control valve 220 into the tank 222, thereby decreasing the mass of the refrigerant present within the refrigeration circuit 202. Conversely, to increase the mass of the refrigerant within the refrigeration circuit 202, the first control valve 220 is closed and the second control valve 224 is opened. In such instances, refrigerant stored within the tank 222 flows through the second control valve 224 into the refrigeration circuit 202, thereby increasing the mass of the refrigerant within the refrigeration circuit 202.

In some embodiments, the refrigerant charge control device 204 does not require a pump to remove refrigerant from or add refrigerant to the refrigeration circuit 202. Specifically, when the first control valve 220 is opened and the second control valve 224 is closed, the pressure of the refrigerant within the refrigeration circuit 202 causes a portion of the refrigerant to flow through the first control valve 220 and into the tank 222. Similarly, when the first control valve 220 is closed and the second control valve 224 is opened, the pressure of the refrigerant within the tank 222 causes a portion of the refrigerant to flow through the second control valve 224 and into the refrigeration circuit 202.

Additionally, in several embodiments, the vapor cycle system 200 includes a pressure sensor 226. In general, the pressure sensor 226 is configured to capture data indicative of the pressure of the refrigerant exiting the second condenser 214 (or the last condenser through which the refrigerant flows before reaching the expansion valves 216, 218). As such, the pressure sensor 226 may be fluidly coupled to the refrigeration circuit 202 adjacent to the outlet (not shown) of the second condenser 214. The pressure sensor 226 may correspond to any suitable device for capturing data indicative of the pressure of the refrigerant, such as a piezoresistive strain gauge, an electromagnetic pressure sensor, and/or the like.

Moreover, in several embodiments, the vapor cycle system 200 includes a temperature sensor 228. In general, the temperature sensor 228 is configured to capture data indicative of the temperature of the refrigerant exiting the second condenser 214 (or the last condenser through which the refrigerant flows before reaching the expansion valves 216, 218). As such, the temperature sensor 228 may be fluidly coupled to the refrigeration circuit 202 adjacent to the outlet (not shown) of the second condenser 214. The temperature sensor 228 may correspond to any suitable device for capturing data indicative of the temperature of the refrigerant, such as a thermistor, a thermocouple and/or the like.

Furthermore, in several embodiments, the vapor cycle system 200 includes a computing system 230 communicatively coupled to one or more components of the vapor cycle system 200 to allow the computing system 230 to electronically or automatically control the operation of such components. For instance, the computing system 230 may be communicatively coupled to the pressure and temperature sensors 226, 228 via a communicative link 232. In this respect, the computing system 230 may be configured to receive data indicative of the temperature and/or the pressure of the refrigerant exiting the second condenser 214 (or the last condenser through which the refrigerant flows before reaching the expansion valves 216, 218). Moreover, the computing system 230 may be communicatively coupled to the first and second control valves 220, 224 via the communicative link 232. As such, the computing system 230 may be configured to control the operation of the first and second valves 220, 224 to adjust the mass of the refrigerant within the refrigeration circuit 202 based on the received pressure and/or temperature sensor data. Additionally, the computing system 230 may be communicatively coupled to any other suitable components of the vapor cycle system via the communicative link 232.

In general, the computing system 230 may comprise one or more processor-based devices, such as a given controller or computing device or any suitable combination of controllers or computing devices. Thus, in several embodiments, the computing system 230 may include one or more processor(s) 234 and associated memory device(s) 236 configured to perform a variety of computer-implemented functions. As used herein, the term “processor” refers not only to integrated circuits referred to in the art as being included in a computer, but also refers to a controller, a microcontroller, a microcomputer, a programmable logic circuit (PLC), an application specific integrated circuit, and other programmable circuits. Additionally, the memory device(s) 236 of the computing system 230 may generally comprise memory element(s) including, but not limited to, a computer readable medium (e.g., random access memory RAM)), a computer readable non-volatile medium (e.g., a flash memory), a floppy disk, a compact disk-read only memory (CD-ROM), a magneto-optical disk (MOD), a digital versatile disk (DVD) and/or other suitable memory elements. Such memory device(s) 236 may generally be configured to store suitable computer-readable instructions that, when implemented by the processor(s) 234, configure the computing system 230 to perform various computer-implemented functions, such as one or more aspects of the methods and algorithms that will be described herein. In addition, the computing system 230 may also include various other suitable components, such as a communications circuit or module, one or more input/output channels, a data/control bus and/or the like.

The various functions of the computing system 230 may be performed by a single processor-based device or may be distributed across any number of processor-based devices. In such instances, such processor-based devices may form part of the computing system 230. For instance, the functions of the computing system 230 may be distributed across multiple application-specific controllers, such an engine controller, a navigation controller, a communications controller, and/or the like.

In several embodiments, the computing system 230 is configured to monitor the pressure and/or the temperature of the refrigerant exiting the second condenser 214 (or the last condenser through which the refrigerant flows before reaching the expansion valves 216, 218). More specifically, during operation of the vapor cycle system 200, the computing system 230 is configured to receive data captured by the pressure and/or temperature sensors 226, 228 (e.g., via the communicative link 232). The computing system 230 is configured to process/analyze the received sensor data to determine the pressure and/or temperature of the refrigerant exiting the second condenser 214. For example, the computing system 230 may include a suitable look-up table stored within its memory device(s) 112 that respectively correlates the received pressure and temperature data to the pressure and/or temperature of the refrigerant exiting the second condenser 214.

Furthermore, in several embodiments, the computing system 230 is configured to determine a subcool value of the refrigerant exiting the second condenser 214 (or the last condenser through which the refrigerant flows before reaching the expansion valves 216, 218) based on the monitored temperature and pressure. In general, the subcool value is the number of degrees that the monitored temperature is below the saturation temperature of the refrigerant. As such, the computing system 230 may include a suitable look-up table or mathematical formula stored within its memory device(s) 112 that correlates the monitored temperature and pressure to the subcool value.

Additionally, in several embodiments, the computing system 230 is configured to control the operation of the refrigerant charge control device 204 to adjust the mass of the refrigerant flowing through the refrigeration circuit 230 based on the monitored pressure. More specifically, the compressor 210 may experience high wear, become damaged, or stall when the pressure of the refrigerant exiting the second condenser 214 (or the last condenser through which the refrigerant flows before reaching the expansion valves 216, 218) becomes too high. In such instances, the use of the condenser 212, 214 that is currently rejecting heat from the refrigeration circuit 202 may necessitate a smaller mass of refrigerant within the refrigeration circuit 202 to properly operate. In this respect, the computing system 230 may be configured to compare the monitored pressure to a maximum pressure value. Thereafter, when the monitored pressure exceeds the maximum pressure value (thereby indicating that the pressure of the refrigerant within the refrigeration circuit 202 is too high), the computing system 230 controls the operation of the refrigerant charge control device 204 such that the mass of the refrigerant within the refrigeration circuit 202 is decreased. For example, in such instances, the computing system 230 may be configured to control the operation of the refrigerant charge control device 204 such that the first control valve 220 is opened and the second control valve 224 is closed or placed within a weeping position. As described above, when the first control valve 220 is opened and the second control valve 224 is closed, a portion of the refrigerant flows from the refrigeration circuit 202 into the tank 222, thereby decreasing the mass of the of the refrigerant within the refrigeration circuit 202.

Moreover, in several embodiments, the computing system 230 is configured to control the operation of the refrigerant charge control device 204 to adjust the mass of the refrigerant flowing through the refrigeration circuit 230 based on the monitored temperature and pressure. More specifically, when the subcool value of the refrigerant exiting the second condenser 214 (or the last condenser through which the refrigerant flows before reaching the expansion valves 216, 218) becomes too low, vaporized refrigerant may flow through the expansion valves 216, 218, thereby causing the valves 216, 218 to hunt or become overly restricted. In such instances, the use of the condenser 212, 214 that is currently rejecting heat from the refrigeration circuit 202 may necessitate a larger mass of refrigerant within the refrigeration circuit 202 to properly operate. In this respect, the computing system 230 may be configured to compare the determined subcool value to a minimum subcool value. Thereafter, when the determined subcool value exceeds the minimum subcool value (thereby indicating that the subcool value of the refrigerant within the refrigeration circuit 202 is too low), the computing system 230 controls the operation of the refrigerant charge control device 204 such that the mass of the refrigerant within the refrigeration circuit 202 is increased. For example, in such instances, the computing system 230 may be configured to control the operation of the refrigerant charge control device 204 such that the first control valve 220 is closed and the second control valve 224 is opened. As described above, when the first control valve 220 is closed and the second control valve 224 is opened, a portion of the refrigerant flows from the tank 222 into the refrigeration circuit 202, thereby increasing the mass of the of the refrigerant within the refrigeration circuit 202.

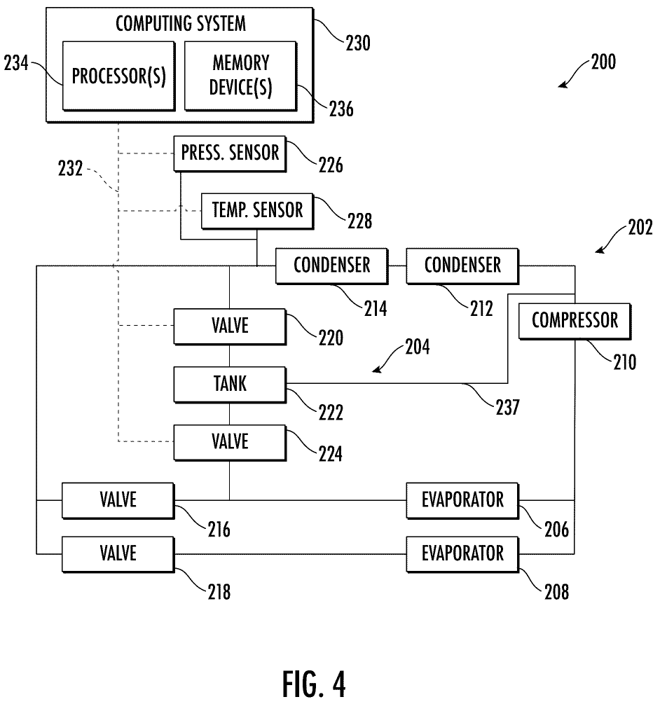

FIG. 4 is a schematic view of another embodiment of a vapor cycle system 200 for cooling components. Like the embodiment of the vapor cycle system 200 shown in FIG. 3, the vapor cycle system 200 shown in FIG. 4 includes a refrigeration circuit 202 having first and second evaporators 206, 208; a compressor 210; a first condenser 214; a second condenser 216 in series with the first condenser 214; and first and second expansion valves 216, 218. Moreover, like the embodiment of the vapor cycle system 200 shown in FIG. 3, the vapor cycle system 200 shown in FIG. 4 also includes a refrigerant charge control device 204 having a first valve 220, a tank 224, and a second valve 226.

However, unlike the embodiment shown in FIG. 3, the vapor cycle system 200 shown in FIG. 4 includes a hot gas injection line 237. In general, the hot gas injection line 237 supplies hot gaseous refrigerant that has been compressed by the compressor 210 (and before such refrigerant has been compressed) to the tank 222. In this respect, when the second control valve 224 is opened and the first control valve 220 is closed (i.e., when the mass of the refrigerant in the refrigeration circuit 202 is being increased), the hot gaseous refrigerant facilitates transfer of the refrigerant stored within the tank 222 to the refrigeration circuit 202. Specifically, the hot gaseous refrigerant forces refrigerant out of the tank 222 when the pressure within the refrigerant charge control device 204 is too low to do so. As such, the hot gas injection line 237 extends from the refrigeration circuit 202 to the tank 222.

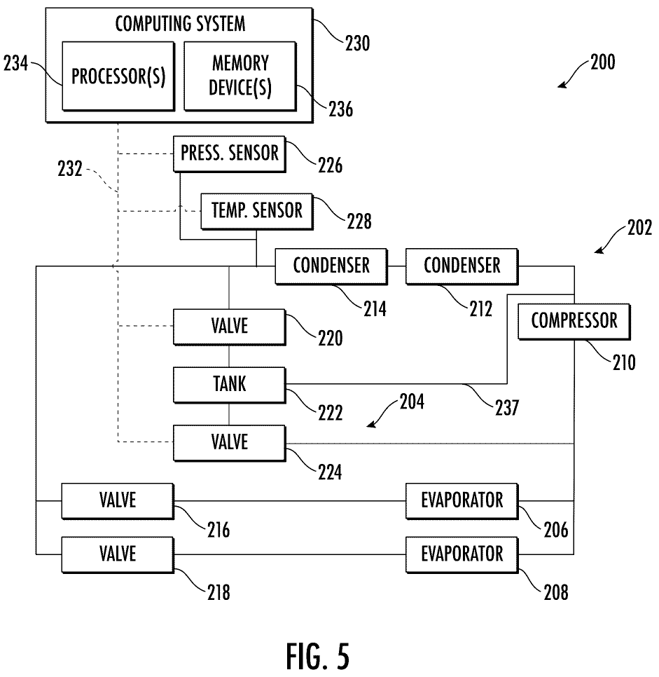

FIG. 5 is a schematic view of a further embodiment of a vapor cycle system 200 for cooling components. Like the embodiments of the vapor cycle system 200 shown in FIGS. 3 and 4, the vapor cycle system 200 shown in FIG. 5 includes a refrigeration circuit 202 having first and second evaporators 206, 208; a compressor 210; a first condenser 214; a second condenser 216 in series with the first condenser 214; and first and second expansion valves 216, 218. Moreover, like the embodiment of the vapor cycle system 200 shown in FIGS. 3 and 4, the vapor cycle system 200 shown in FIG. 5 also includes a refrigerant charge control device 204 having a first valve 220, a tank 224, and a second valve 226 as well as a hot gas injection line 237.

However, unlike the embodiments shown in FIGS. 3 and 4, in the vapor cycle system 200 shown in FIG. 5, the refrigerant charge control device 204 is coupled to the refrigeration circuit 202 such that the refrigerant being added to the refrigeration circuit 202 from the tank 222 bypasses the evaporators 206, 208. That is, when the second control valve 224 is opened and the first control valve 220 is closed, the refrigerant from the tank 222 enters the refrigeration circuit 202 downstream of the evaporators 206, 208 and upstream of the compressor 210. The embodiment of the vapor cycle system 200 shown in FIG. 5 is less efficient than the embodiments of the vapor cycle system 200 shown in FIGS. 3 and 4 because allowing the added refrigerant to bypass the evaporators 206, 208 increases the mass of the refrigerant that the compressor 210 must compress. However, the embodiment of the vapor cycle system 200 shown in FIG. 5 provides better protection to the compressor 210 than the embodiments of the vapor cycle system 200 shown in FIGS. 3 and 4 because allowing the added refrigerant to bypass the evaporators 206, 208 cools the refrigerant entering the compressor 210.

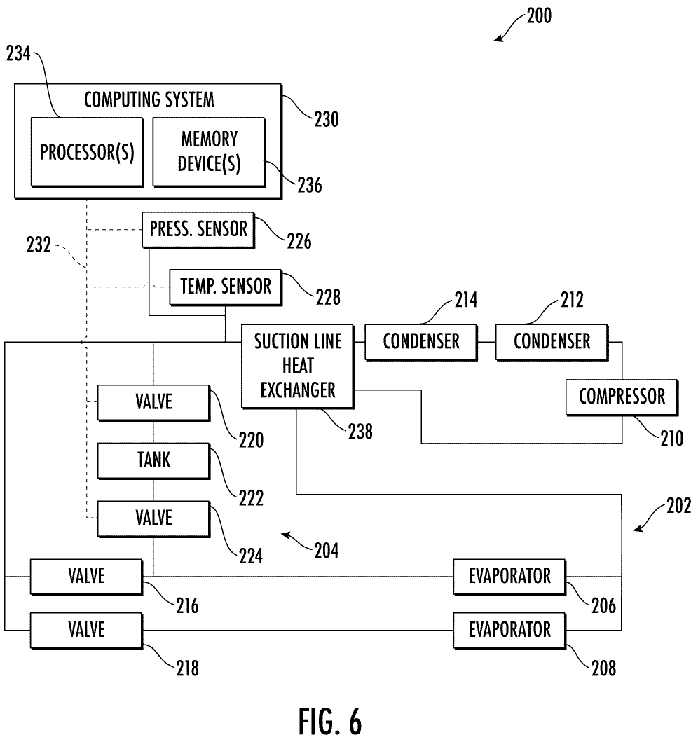

FIG. 6 is a schematic view of another embodiment of a vapor cycle system 200 for cooling components. Like the embodiments of the vapor cycle system 200 shown in FIGS. 3-5, the vapor cycle system 200 shown in FIG. 6 includes a refrigeration circuit 202 having first and second evaporators 206, 208; a compressor 210; a first condenser 214; a second condenser 216 in series with the first condenser 214; and first and second expansion valves 216, 218. Moreover, like the embodiment of the vapor cycle system 200 shown in FIGS. 3-5, the vapor cycle system 200 shown in FIG. 6 also includes a refrigerant charge control device 204 having a first valve 220, a tank 224, and a second valve 226.

However, unlike the embodiment shown in FIGS. 3-5, the vapor cycle system 200 shown in FIG. 6 includes a suction line heat exchanger 238. In general, the suction line heat exchanger 238 is configured to transfer heat from the refrigerant exiting the second condenser 214 (or the last condenser through which the refrigerant flows before reaching the expansion valves 216, 218) to the refrigerant entering the compressor 210. In this respect, as shown in FIG. 6, the suction line heat exchanger 238 is positioned within the refrigeration circuit 202 such that refrigerant exiting the second condenser 214 flows through the suction line heat exchanger 238 before reaching the refrigerant charge control device 204 and the expansion valves 216, 218. Furthermore, as shown in FIG. 6, the suction line heat exchanger 238 is positioned within the refrigeration circuit 202 such that refrigerant exiting the first and second evaporators 206, 208 flows through the suction line heat exchanger 238 before reaching the compressor 210.

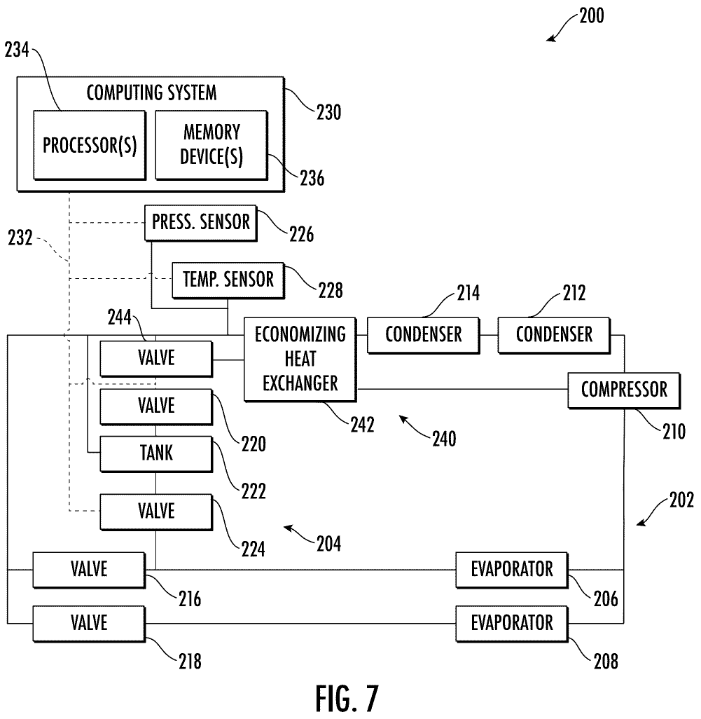

FIG. 7 is a schematic view of a further embodiment of a vapor cycle system 200 for cooling components. Like the embodiments of the vapor cycle system 200 shown in FIGS. 3-6, the vapor cycle system 200 shown in FIG. 7 includes a refrigeration circuit 202 having first and second evaporators 206, 208; a compressor 210; a first condenser 214; a second condenser 216 in series with the first condenser 214; and first and second expansion valves 216, 218. Moreover, like the embodiments of the vapor cycle system 200 shown in FIGS. 3-6, the vapor cycle system 200 shown in FIG. 7 also includes a refrigerant charge control device 204 having a first valve 220, a tank 224, and a second valve 226.

However, unlike the embodiments shown in FIGS. 3-6, the vapor cycle system 200 shown in FIG. 7 includes a bypass circuit 240 in fluid communication with the refrigeration circuit 202. In general, the bypass circuit 240 is configured to permit a portion of the refrigerant exiting the second condenser 214 (or the last condenser through which the refrigerant flows before reaching the expansion valves 216, 218) to bypass the expansion valves 216, 218 and the evaporators 206, 208 and flow directly to the compressor 210. Moreover, as shown, the bypass circuit 240 includes an economizing heat exchanger 242 and a third control valve 244 configured to control a flow of the refrigerant from the refrigeration circuit 202 into the bypass circuit 240. As such, in operation, the refrigerant exiting the second condenser 214 flows through the economizing heat exchanger 242. The third control valve 244 may be opened (e.g., based on control signals transmitted to the valve 224 from the computing system 230 via the communicative link 232) to allow a portion of the refrigerant exiting the economizing heat exchanger 242 to flow into the bypass circuit 240. The refrigerant within the bypass circuit 240 then flows back through the through the economizing heat exchanger 242 such that heat is transferred from the refrigerant exiting the second condenser 214 to the refrigerant flowing through the bypass circuit 240. Thereafter, the refrigerant within the bypass circuit 240 flows to the compressor 210.

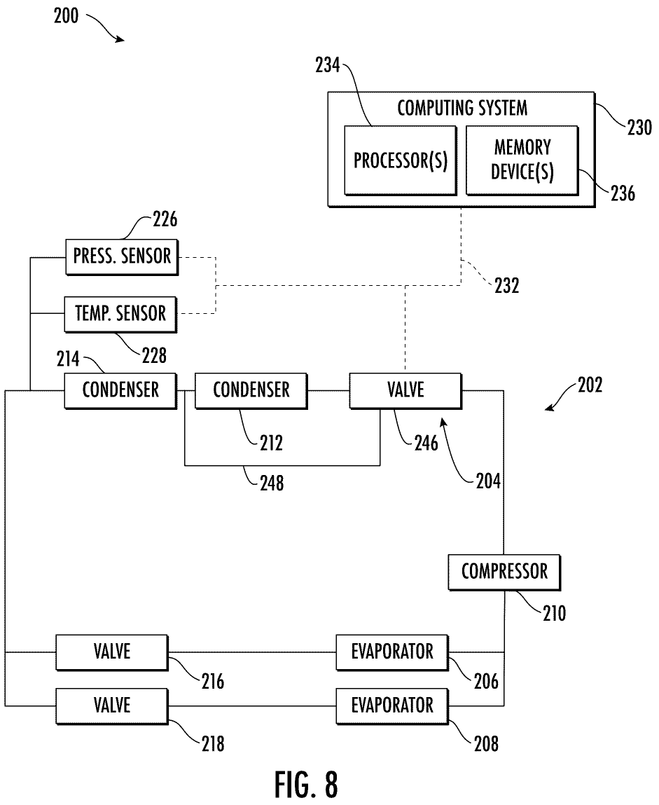

FIG. 8 is a schematic view of yet another embodiment of a vapor cycle system 200 for cooling components. Like the embodiments of the vapor cycle system 200 shown in FIGS. 3-7, the vapor cycle system 200 shown in FIG. 8 includes a refrigeration circuit 202 having first and second evaporators 206, 208; a compressor 210; a first condenser 214; a second condenser 216 in series with the first condenser 214; and first and second expansion valves 216, 218. Moreover, like the embodiments of the vapor cycle system 200 shown in FIGS. 3-7, the vapor cycle system 200 shown in FIG. 8 also includes a refrigerant charge control device 204.

However, unlike the embodiments shown in FIGS. 3-7, the refrigerant charge control device 204 shown in FIG. 8 corresponds to a control valve 246 fluidly coupled to the refrigeration circuit 202 in series. Specifically, as shown in FIG. 8, in the illustrated embodiment, the control valve 246 is positioned such that the refrigerant exiting the compressor 210 flows through the control valve 246 before entering the first condenser 212 (or the first condenser through which the refrigerant flows after exiting the compressor 210). Additionally, the control valve 246 may be communicatively coupled to the computing system 230 (e.g., via the communicative link 232) such that the computing system 230 is able to control the operation of the control valve 246.

Furthermore, in the embodiment shown in FIG. 8, the vapor cycle system 200 includes a bypass circuit 248 in fluid communication with the refrigeration circuit 202. In general, the bypass circuit 248 configured to permit the refrigerant to bypass the first condenser 212. As such, the bypass circuit 248 may be fluidly coupled to and extend from the control valve 246 to a location on the refrigeration circuit 202 between the first and second condensers 212, 214. In such embodiments, the control valve 246 is configured to selectively permit the refrigerant from the refrigeration circuit 202 to flow into the bypass circuit 248. In this respect, when the control valve 248 is at a first position, the control valve 248 may direct the flow of the refrigerant through the refrigeration circuit 202 into the first condenser 212 and block the flow of the refrigerant into the bypass circuit 248. Conversely, when the control valve 248 is at a second position, the control valve 248 may direct the flow of the refrigerant through the refrigeration circuit 202 into the bypass circuit 248 and block the flow of the refrigerant into the first condenser 212.

In several embodiments, the control valve 246 is used to adjust the mass of refrigerant flowing through the refrigeration circuit 202. More specifically, as described above, the mass of refrigerant flowing through the refrigeration circuit 202 may be adjusted based on the pressure and/or the temperature of the refrigerant exiting the second condenser 214 (or the last condenser through which the refrigerant flows before reaching the expansion valves 216, 218). In this respect, when the monitored pressure of the refrigerant exceeds the maximum pressure value (and the first condenser 212 is not being used to reject heat from the refrigeration circuit 202), the computing system 230 may be configured to control the operation of the control valve 246 such that the control valve 246 is moved to the second position. In such instances, the refrigerant within the refrigeration circuit 202 flows into the bypass circuit 248. Once the refrigerant bypasses the first condenser 212 and reenters the refrigeration circuit 202, a portion of the refrigerant flows backward into the outlet (not shown) of the first condenser 212, thereby backfilling the first condenser 212. Such backfilling reduces the mass of the refrigerant flowing through the second condenser 214; the expansion valves 216, 218; the evaporators 206, 208; and the compressor 210. In order to effectively back fill, a small amount of thermal sink may need to be provided to the first condenser 212 to liquify the stagnant mass of refrigerant. Conversely, when the determined subcool value of the refrigerant falls below a minimum subcool value, the computing system 230 may be configured to control the operation of the control valve 246 such that the control valve 246 is moved to the first position. In such instances, the refrigerant exiting the compressor 210 flows into the inlet (not shown) of the first condenser 212 and is blocked from entering the bypass circuit 248. The flow the refrigerant through the first condenser 212 causes any refrigerant stored within the first condenser 212 due to backfilling to exit the first condenser 212 and flow into the second condenser 214. This, in turn, increases the mass of the refrigerant flowing through the second condenser 214; the expansion valves 216, 218; the evaporators 206, 208; and the compressor 210.

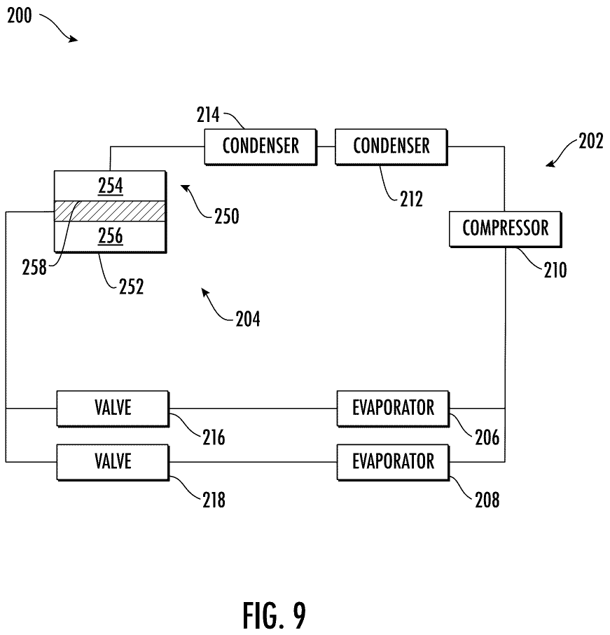

FIG. 9 is a schematic view of yet a further embodiment of a vapor cycle system 200 for cooling components. Like the embodiments of the vapor cycle system 200 shown in FIGS. 3-8, the vapor cycle system 200 shown in FIG. 9 includes a refrigeration circuit 202 having first and second evaporators 206, 208; a compressor 210; a first condenser 214; a second condenser 216 in series with the first condenser 214; and first and second expansion valves 216, 218. Moreover, like the embodiments of the vapor cycle system 200 shown in FIGS. 3-8, the vapor cycle system 200 shown in FIG. 9 also includes a refrigerant charge control device 204.

However, unlike the embodiments shown in FIGS. 3-8, the refrigerant charge control device 204 shown in FIG. 9 corresponds to a storage device 250. Specifically, as shown in FIG. 9, in the illustrated embodiment, the storage device 250 includes a cylinder 252 defining a first chamber 254 and a second chamber 256. Furthermore, the storage device 250 includes a piston or diaphragm 258 positioned within the cylinder 252 to separate the first and second chambers 254, 256. The piston 258 is, in turn, movable within the cylinder 252 such that the sizes of the first and second chambers 254, 256 can be varied. Moreover, the first chamber 254 is fluid coupled to the refrigeration circuit 202 in series such that the refrigerant exiting the second condenser 214 (or the last condenser through which the refrigerant flows before reaching the expansion valves 216, 218) flows through the first chamber 254 before reaching the expansion valves 216, 218. Additionally, the second chamber 256 is filled within a fluid under a predetermined pressure (e.g., compressed air, hydraulic oil, etc.). However, in alternative embodiments, the storage device 250 may correspond to any other suitable device for storing refrigerant, such as a bladder, a welded bellows, a piston, and/or the like.

In operation, the storage device 250 shown in FIG. 9 passively controls the mass of the refrigerant flowing through the refrigeration circuit 202. More specifically, as mentioned above, the second chamber 256 of the cylinder 252 is filled with a fluid under a predetermined pressure. In this respect, when the pressure of the refrigerant exiting the second condenser 214 is greater than the pressure of the fluid within the second chamber 256 (thereby indicating the pressure of the refrigerant within the refrigeration circuit 202 is too high), the piston 258 moves within the cylinder 252 such that the size of the first chamber 254 increases and the size of the second chamber 256 decreases. Such an increase in the size of the first chamber 254 allows more refrigerant to be stored within the first chamber 254, thereby reducing the mass the refrigerant flowing through the refrigeration circuit 202, namely the condensers 212, 214; the expansion valves 216, 218; the evaporators 206, 208; and the compressor 210. Conversely, when pressure of the refrigerant exiting the second condenser 214 is less than the pressure of the fluid within the second chamber 256 (thereby indicating that the pressure of the refrigerant within the refrigeration circuit 202 is too low), the piston 258 moves within the cylinder 252 such that the size of the first chamber 254 decreases and the size of the second chamber 256 increases. Such a decrease in the size of the first chamber 254 allows less refrigerant to be stored within the first chamber 254, thereby increasing the mass the refrigerant flowing through the refrigeration circuit 202, namely the condensers 212, 214; the expansion valves 216, 218; the evaporators 206, 208; and the compressor 210.

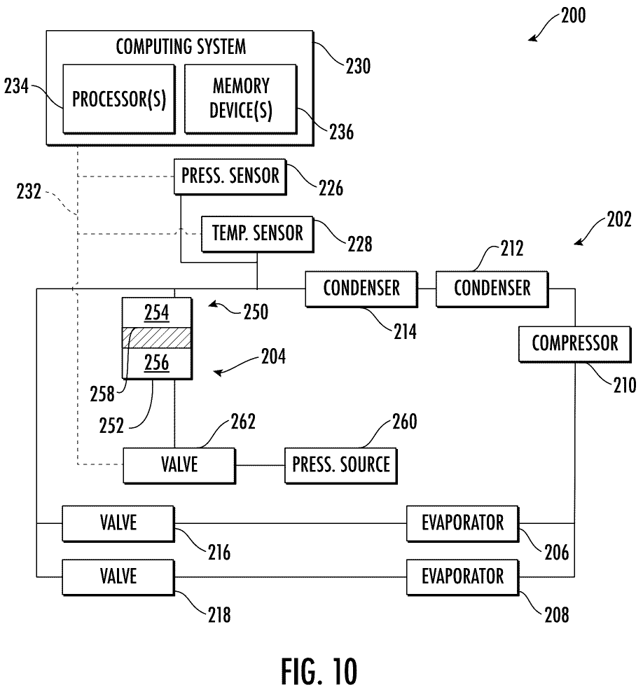

FIG. 10 is a schematic view of another embodiment of a vapor cycle system 200 for cooling components. Like the embodiment of the vapor cycle system 200 shown in FIG. 9, the vapor cycle system 200 shown in FIG. 10 includes a refrigeration circuit 202 having first and second evaporators 206, 208; a compressor 210; a first condenser 214; a second condenser 216 in series with the first condenser 214; and first and second expansion valves 216, 218. Moreover, like the embodiment of the vapor cycle system 200 shown in FIG. 9, the vapor cycle system 200 shown in FIG. 10 also includes a refrigerant charge control device 204 having a storage device 250. The storage device 250, in turn, includes a cylinder 252 defining a first chamber 254 and a second chamber 256 separated by a piston or diaphragm 258.

However, unlike the embodiments shown in FIG. 9, the refrigerant charge control device 204 shown in FIG. 10 also includes a pressure source 260 (e.g., a pump, a plenum, etc.) and a control valve 262. More specifically, as shown, the pressure source 260 and the control valve 262 are in fluid communication with the second chamber 256. As such, the pressure source 260 is configured to generate and/or storage a pressurized fluid (e.g., air, hydraulic oil, fuel, etc.). Furthermore, the control valve 262 is configured to control the flow of the pressurized fluid from the pressure source 260 to the second chamber 256. Moreover, the control valve 262 may allow fluid to be removed from the second chamber 256 and transferred to a reservoir (not shown). Additionally, in some embodiments, the control valve 262 may be communicatively coupled to the computing system 230 (e.g., via the communicative link 232) such that the computing system 230 is able to control the operation of the control valve 262.

In operation, the refrigerant charge control device 204 shown in FIG. 10 actively controls the mass of the refrigerant flowing through the refrigeration circuit 202. More specifically, as described above, the mass of refrigerant within the refrigeration circuit 202 may be adjusted based on the pressure and/or the temperature of the refrigerant exiting the second condenser 214 (or the last condenser through which the refrigerant flows before reaching the expansion valves 216, 218). In this respect, when the monitored pressure of the refrigerant exceeds the maximum pressure value, the computing system 230 may be configured to control the operation of the control valve 262 such that the control valve 262 allows fluid to exit the second chamber 256 and flow to a reservoir (not shown). In such instances, the size of the first chamber 254 increases and the size of the second chamber 256 decreases. Such an increase in the size of the first chamber 254 allows more refrigerant to be stored within the first chamber 254, thereby reducing the mass the refrigerant flowing through the refrigeration circuit 202, namely the condensers 212, 214; the expansion valves 216, 218; the evaporators 206, 208; and the compressor 210. Conversely, when the determined subcool value of the refrigerant falls below a minimum subcool value, the computing system 230 may be configured to control the operation of the control valve 262 such that the control valve 262 is opened to allow pressurized fluid from the pressure source to flow into the second chamber 256 of the cylinder 252. In such instances, the size of the first chamber 254 decreases and the size of the second chamber 256 increases. Such a decrease in the size of the first chamber 254 allows less refrigerant to be stored within the first chamber 254, thereby increasing the mass the refrigerant flowing through refrigeration circuit 202, namely the condensers 212, 214; the expansion valves 216, 218; the evaporators 206, 208; and the compressor 210.

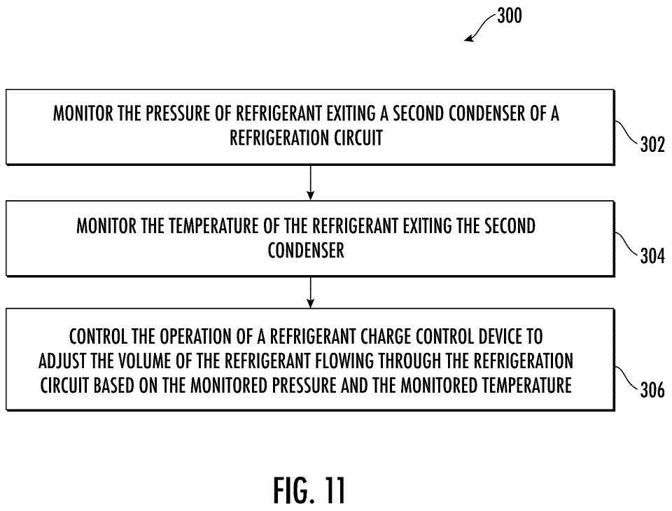

FIG. 11 is a flow diagram of one embodiment of a method 300 for cooling components using a vapor cycle system. In general, the method 300 will be described herein with reference to the system 200 described above and shown in FIGS. 3-10. However, the disclosed method 300 may be implemented within any system having any other suitable system configuration. In addition, although FIG. 11 depicts steps performed in a particular order for purposes of illustration and discussion, the methods discussed herein are not limited to any particular order or arrangement. One skilled in the art, using the disclosures provided herein, will appreciate that various steps of the methods disclosed herein can be omitted, rearranged, combined, and/or adapted in various ways without deviating from the scope of the present disclosure.

As shown in FIG. 11, at (302), the method 300 includes monitoring, with a computing system, a pressure of refrigerant exiting a second condenser of a refrigeration circuit of the vapor cycle system. For example, as described above, the computing system 230 may be configured to monitor the pressure of refrigerant exiting the second condenser 214 (or the last condenser through which the refrigerant flows before reaching the expansion valves 216, 218) of the refrigeration circuit 202 of the vapor cycle system 200 based on data captured by a pressure sensor 226.

Additionally, at (304), the method 300 may include monitoring, with the computing system, a temperature of the refrigerant exiting the second condenser. For example, as described above, the computing system 230 may be configured to monitor the temperature of the refrigerant exiting the second condenser 214 (or the last condenser through which the refrigerant flows before reaching the expansion valves 216, 218) based on data captured by a temperature sensor 228.

Moreover, as shown in FIG. 11, at (306), the method 300 may include controlling, with the computing system, an operation of the refrigerant charge control device to adjust the mass of the refrigerant flowing through the refrigeration circuit based on the monitored pressure and the monitored temperature. For example, as described above, the computing system 230 may be configured to control the operation of the refrigerant charge control device 204 of the vapor cycle system 200 to adjust the mass of the refrigerant flowing through the refrigeration circuit 202 based on the monitored pressure and the monitored temperature.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal language of the claims.

Further aspects of the invention are provided by the subject matter of the following clauses:

A vapor cycle system for cooling components, the system comprising: a refrigeration circuit through which a mass of a refrigerant flows, the refrigeration circuit comprising: a compressor; a first condenser; a second condenser fluidly coupled to the first condenser in series; an expansion valve; and an evaporator; and a refrigerant charge control device configured to increase or decrease the mass of the refrigerant flowing through the refrigeration circuit, wherein the refrigerant charge control device comprises a storage device.

The system of one or more of these clauses, wherein the refrigerant charge control device is in parallel with the expansion valve.

The system of one or more of these clauses, wherein the refrigerant charge control device comprises a control valve.

The system of one or more of these clauses, wherein: the control valve corresponds to a first control valve; the refrigerant charge control device further comprises a tank in series with the first control valve and a second control valve in series with the tank; when the first control valve is opened, a portion of the refrigerant flows from the refrigeration circuit into the tank; and when the second control valve is opened, a portion of the refrigerant flows from the tank into the refrigeration circuit.

The system of one or more of these clauses, wherein, when the second control valve is opened, the portion of the refrigerant passively flows from the tank into the refrigeration circuit.

The system of one or more of these clauses, wherein the refrigeration circuit further comprises a suction line heat exchanger configured to transfer heat between a portion of the refrigerant flowing from the second condenser to the expansion valve and a portion of the refrigerant flowing from the evaporator to the compressor.

The system of one or more of these clauses, further comprising: a bypass circuit in fluid communication with the refrigeration circuit, the bypass circuit configured to permit a portion of the refrigerant exiting the second condenser to bypass the expansion valve and the evaporator and flow directly to the compressor, the bypass circuit including an economizing heat exchanger and a third control expansion valve configured to control a flow of the refrigerant from the refrigeration circuit into the bypass circuit.

The system of one or more of these clauses, further comprising: a bypass circuit in fluid communication with the refrigeration circuit, the bypass circuit configured to permit the refrigerant to bypass the first condenser, wherein the control valve is configured to selectively permit the refrigerant from the refrigeration circuit to flow into the bypass circuit.

The system of one or more of these clauses, wherein the first condenser is configured to be backfilled with a portion of the refrigerant that bypassed the first condenser.

The system of one or more of these clauses, wherein the refrigerant charge control device comprises a storage device.

The system of one or more of these clauses, wherein the storage device is configured to passively control the mass of the refrigerant flowing through the refrigeration circuit.

The system of one or more of these clauses, wherein the storage device is configured to actively control the mass of the refrigerant flowing through the refrigeration circuit.

The system of one or more of these clauses, wherein the storage device comprises: a cylinder defining a first chamber and a second chamber; and a piston separating the first chamber and the second chamber.

The system of one or more of these clauses, wherein the storage device is in series with the refrigeration circuit.

The system of one or more of these clauses, further comprising: a pressure sensor configured to capture data indicative of a pressure of the refrigerant exiting the second condenser; a temperature sensor configured to capture data indicative of a temperature of the refrigerant exiting the second condenser; a computing system communicatively coupled to the pressure sensor and the temperature sensor, the computing system configured to: monitor the pressure of the refrigerant exiting the second condenser based on the data captured by the pressure sensor; monitor the temperature of the refrigerant exiting the second condenser based on the data captured by the temperature sensor; and control an operation of the refrigerant charge control device to adjust the mass of the refrigerant flowing through the refrigeration circuit based on the monitored pressure and the monitored temperature.

The system of one or more of these clauses, wherein, when controlling the operation of the refrigerant charge control device, the computing system is further configured to: compare the monitored pressure to a maximum pressure value; and when the monitored pressure exceeds the maximum pressure value, control the operation of the refrigerant charge control device such that the mass of the refrigerant flowing through the refrigeration circuit is decreased.

The system of one or more of these clauses, wherein, when controlling the operation of the refrigerant charge control device, the computing system is further configured to: determine a subcool value of the refrigerant exiting the second condenser based on the monitored temperature; compare the determined subcool value to a minimum subcool value; and when the determined subcool value falls below the minimum subcool value, control the operation of the refrigerant charge control device such that the mass of the refrigerant flowing through the refrigeration circuit is increased.

A method for cooling components using a vapor cycle system, the vapor cycle system including a refrigeration circuit through which a mass of a refrigerant flows, the refrigeration circuit including a first condenser and a second condenser fluidly coupled to the first condenser in series, the vapor cycle system further including a refrigerant charge control device configured to increase or decrease the mass of the refrigerant flowing through the refrigeration circuit, the method comprising: monitoring, with a computing system, a pressure of the refrigerant exiting the second condenser; monitoring, with the computing system, a temperature of the refrigerant exiting the second condenser; and controlling, with the computing system, an operation of the refrigerant charge control device to adjust the mass of the refrigerant flowing through the refrigeration circuit based on the monitored pressure and the monitored temperature.

The method of claim 18, wherein controlling the operation of the refrigerant charge control device comprises: comparing, with the computing system, the monitored pressure to a maximum pressure value; and when the monitored pressure exceeds the maximum pressure value, controlling, with the computing system, the operation of the refrigerant charge control device such that the mass of the refrigerant flowing through the refrigeration circuit is decreased.

The system of claim 18, wherein controlling the operation of the refrigerant charge control device comprises: determining, with the computing system, a subcool value of the refrigerant exiting the second condenser based on the monitored temperature; comparing, with the computing system, the determined subcool value to a minimum subcool value; and when the determined subcool value falls below the minimum subcool value, controlling, with the computing system, the operation of the refrigerant charge control device such that the mass of the refrigerant flowing through the refrigeration circuit is increased.

What is claimed is:

1. A vapor cycle system for cooling components, the system comprising:
a refrigeration circuit through which a mass of a refrigerant flows, the refrigeration circuit comprising:
a compressor;
a first condenser;
a second condenser fluidly coupled to the first condenser in series;
an expansion valve;
an evaporator; and
a refrigerant charge control device configured to increase or decrease the mass of the refrigerant flowing through the refrigeration circuit, wherein the refrigerant charge control device comprises a storage device.

2. The system of claim 1, wherein the refrigerant charge control device is disposed upstream from the expansion valve.

3. The system of claim 1, wherein the storage device is disposed downstream from the first condenser and upstream from the expansion valve.

4. The system of claim 1, wherein the storage device includes a cylinder and a piston disposed within the cylinder.

5. The system of claim 4, wherein the cylinder defines a first chamber and a second chamber, wherein the piston separates the first chamber from the second chamber.

6. The system of claim 5, wherein the refrigeration circuit further comprises a pressure source, wherein the cylinder is fluidly coupled to the pressure source via the second chamber.

7. The system of claim 5, wherein the refrigeration circuit further comprises a pressure source and a control valve, wherein the control valve fluidly couples the pressure source to the second chamber of the cylinder.

8. The system of claim 1, further comprising a temperature sensor disposed between the first condenser and the storage device.

9. The system of claim 1, further comprising a pressure sensor disposed between the first condenser and the storage device.

10. The system of claim 1, wherein the storage device is configured to passively control the mass of the refrigerant flowing through the refrigeration circuit.

11. The system of claim 1, wherein the storage device is configured to actively control the mass of the refrigerant flowing through the refrigeration circuit.

12. The system of claim 1, wherein the storage device is in series with the refrigeration circuit.

13. The system of claim 1, wherein the refrigeration circuit further comprises a second condenser disposed downstream from the first condenser and upstream from the storage device.

14. The system of claim 13, further comprising:
a pressure sensor configured to capture data indicative of a pressure of the refrigerant exiting the second condenser;
a temperature sensor configured to capture data indicative of a temperature of the refrigerant exiting the second condenser;
a computing system communicatively coupled to the pressure sensor and the temperature sensor, the computing system configured to:
monitor the pressure of the refrigerant exiting the second condenser based on the data captured by the pressure sensor;
monitor the temperature of the refrigerant exiting the second condenser based on the data captured by the temperature sensor; and
control an operation of the refrigerant charge control device to adjust the mass of the refrigerant flowing through the refrigeration circuit based on the monitored pressure and the monitored temperature.

15. The system of claim 14, wherein, when controlling the operation of the refrigerant charge control device, the computing system is further configured to:
compare the monitored pressure to a maximum pressure value; and
when the monitored pressure exceeds the maximum pressure value, control the operation of the refrigerant charge control device such that the mass of the refrigerant flowing through the refrigeration circuit is decreased.

16. The system of claim 14, wherein, when controlling the operation of the refrigerant charge control device, the computing system is further configured to:
determine a subcool value of the refrigerant exiting the second condenser based on the monitored temperature;
compare the determined subcool value to a minimum subcool value; and
when the determined subcool value falls below the minimum subcool value, control the operation of the refrigerant charge control device such that the mass of the refrigerant flowing through the refrigeration circuit is increased.

17. A method for cooling components using a vapor cycle system, the vapor cycle system including a refrigeration circuit through which a mass of a refrigerant flows, the refrigeration circuit including a first condenser and a second condenser fluidly coupled to the first condenser in series, the vapor cycle system further including a refrigerant charge control device including a storage device coupled to a pressure source via a control valve and configured to increase or decrease the mass of the refrigerant flowing through the refrigeration circuit, the method comprising:
monitoring, with a computing system, a pressure of the refrigerant exiting the second condenser;
monitoring, with the computing system, a temperature of the refrigerant exiting the second condenser; and
controlling, with the computing system, an operation of the refrigerant charge control device to adjust the mass of the refrigerant flowing through the refrigeration circuit based on the monitored pressure and the monitored temperature.

18. The method of claim 17, wherein controlling the operation of the refrigerant charge control device comprises:
comparing, with the computing system, the monitored pressure to a maximum pressure value; and
when the monitored pressure exceeds the maximum pressure value, controlling, with the computing system, the operation of the refrigerant charge control device such that the mass of the refrigerant flowing through the refrigeration circuit is decreased.

19. The system of claim 17, wherein controlling the operation of the refrigerant charge control device comprises:
determining, with the computing system, a subcool value of the refrigerant exiting the second condenser based on the monitored temperature;
comparing, with the computing system, the determined subcool value to a minimum subcool value; and
when the determined subcool value falls below the minimum subcool value, controlling, with the computing system, the operation of the refrigerant charge control device such that the mass of the refrigerant flowing through the refrigeration circuit is increased.
